(19) United States
(12) Patent Application Publication
(10) Pub. No.: US 2011/0310550 A1
(43) Pub. Date: Dec. 22, 2011

(54) RACK SERVER

(75) Inventors: Ji-Peng Xu, Shanghai City (CN); Tsai-Kuei Cheng, Taipei City (TW)

(73) Assignee: Inventec Corporation, Taipei City (TW)

(21) Appl. No.: 12/840,511

(22) Filed: Jul. 21, 2010

(30) Foreign Application Priority Data
Jun. 17, 2010 (CN) 201010204685.3

(51) Int. Cl. G06F 1/16; H05K 7/20; H05K 5/02; G06F 1/20

(52) U.S. Cl. 361/679.33; 361/679.48; 361/679.47; 361/695; 454/184

(57) ABSTRACT

A rack server including a cabinet, at least one case, at least one replaceable module, and at least one fan is provided. The case is disposed in the cabinet movably and has an opening and a plurality of vents. The replaceable module is moved in or out of the cabinet along a first axis through the opening. The fan is disposed between the cabinet and the case. An air flow generated by the fan flows in or out of the case through the vents. The air flow flows along a second axis in the case. The first axis is substantially perpendicular to the second axis.

### CROSS-REFERENCE TO RELATED APPLICATION

This application claims the priority benefit of China application serial no. 201010204685.3, filed on Jun. 17, 2010. The entirety of the above-mentioned patent application is hereby incorporated by reference herein and made a part of this specification.

### BACKGROUND OF THE INVENTION

1. Field of the Invention

The invention relates to a server and more particularly to a rack server.

2. Description of Related Art

A server is a core computer providing services to every computer in an internet system. The server can function such as a storage disk and provide printing services needed by internet users. The server also allows every user end to share the resources in the internet environment. A basic framework of the server is generally the same as those of conventional personal computers, and is constituted by components including a central processing unit (CPU), a memory, an input/output (I/O) device, and so on. These components are connected in the interior through a bus. The CPU and the memory are connected through a north bridge chip, and the I/O device is connected through a south bridge chip.

A rack server is adopted as an example here. The rack server is a server with an external appearance satisfying a unified standard design and is used in co-operation with a cabinet. Many professional internet apparatuses adopt rack structures, where most of them are flat and resemble a drawer. These professional internet apparatuses are switchboards, routers, hardware firewalls, for example. A width of the rack server is 19 inches, and a height of the rack server is in units of U (1 U=1.75 inches=44.45 millimeter). Usually, there are servers with standards of 1 U, 2 U, 3 U, 4 U, 5 U, and 7 U.

However, since the size of rack servers is much smaller than that of tower servers, the cases thereof are usually disposed with electronic device and heat dissipation apparatuses. Consequently, the rack servers are restrained in heat dissipation. For example, in the rack server of conventional technology, the fan thereof is mostly disposed at a back panel of the case. Therefore, an air flow direction inside the case is consensus with a moving direction of the case. Normally, the configuration of the case has a longer distance between the front side and the back side and a shorter distance from the left side to the right side. The air flow thus has a longer flowing path inside the case, which leads to reduced heat dissipation.

Moreover, the front and the back panels of the case are disposed with various I/O openings simultaneously. The openings adopted as the passages of the air flow and these I/O openings on the case often restrain one another. The power required by the fans inside is also supplied from a power supply to the case through cables. The cables consequently prevent the flowing of the air flow inside the case.

The factors aforementioned interrupt the flowing of the air flow inside the case, thereby reducing the heat dissipation efficiency of the case. Hence, persons skilled in the art need to work on the enhancement of the heat dissipation performance of the rack servers.

### SUMMARY OF THE INVENTION

The invention is directed to a rack server having superior heat dissipation efficiency.

An embodiment of the invention is directed to a rack server including a cabinet, at least one case, at least one replaceable module, and at least one fan. The case is disposed in the cabinet movably and has an opening and a plurality of vents. The fan is disposed between the cabinet and the case, where an air flow generated by the fan flows into and out of the case through the vents. The air flow flows inside the case along a second axis. Here, the first axis is substantially perpendicular to the second axis.

An embodiment of the invention is directed to a rack server including a cabinet, at least one case, at least one replaceable module, and at least one fan. The case is disposed in the cabinet movably and has an opening. The case includes a bottom plate, a back panel and a pair of side plates. The back panel is disposed upright on the bottom plate and opposite to the opening. The side plates are disposed upright on the bottom plate and parallel to each other. The back panel is connected between the side plates and each of the side plates has a plurality of vents. The fan is disposed between the cabinet and at least one of the side plates. An air flow generated by the fan flows into and out of the case through the vents.

An embodiment of the invention is directed to a rack server including a cabinet, at least one case, at least one fan, at least one heat sink fin set, a plurality of hard disks, and a plurality of memory modules. The case is disposed in the cabinet movably and has an opening. The case includes a bottom plate, a back panel and a pair of side plates. The back panel is disposed upright on the bottom plate and opposite to the opening. The side plates are disposed upright on the bottom plate and parallel to each other. The back panel is connected between the side plates and each of the side plates has a plurality of vents. The fan is disposed between the cabinet and at least one of the side plates. An air flow generated by the fan flows into and out of the case through the vents. The heat sink fin set is disposed in the case with fins of the heat sink fin set being perpendicular to the pair of side plates. The memory modules are disposed in the case in an array, wherein a first channel is present between any two memory modules and the first channel is substantially perpendicular to the pair of side plates. The hard disks are disposed in the case in an array, wherein a second channel is present between any two hard disks and the second channel is substantially perpendicular to the pair of side plates.

In light of the foregoing, in the embodiments aforementioned, the rack server utilizes the case and the disposition therein to form a suitable flowing air flow. The disposition includes disposing a plurality of vents on the side plates of the case and disposing electronic devices therein to form channels connecting the vents. As a result, the fan can be disposed beside the side plates outside of the case, so that the air flow generated by the fan flows into and out of the case through the vents. Moreover, a flowing direction of the air flow in the case is perpendicular to a moving axis of the replaceable module in the case due to the component disposition therein, such that the heat dissipation efficiency of the server case is enhanced.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 illustrates a schematic diagram of a rack server according to an embodiment of the invention.

FIG. 2 illustrates a schematic diagram of a case in the rack server shown in FIG. 1.

FIG. 3 is a partial enlarged diagram of the case in FIG. 2.

### DESCRIPTION OF EMBODIMENTS

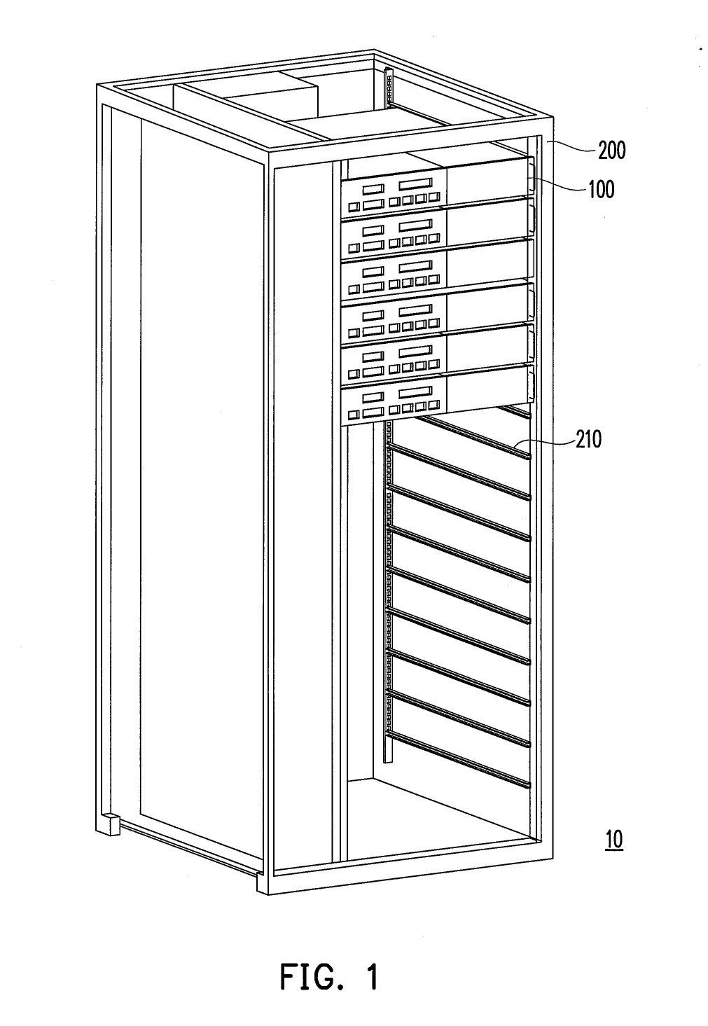

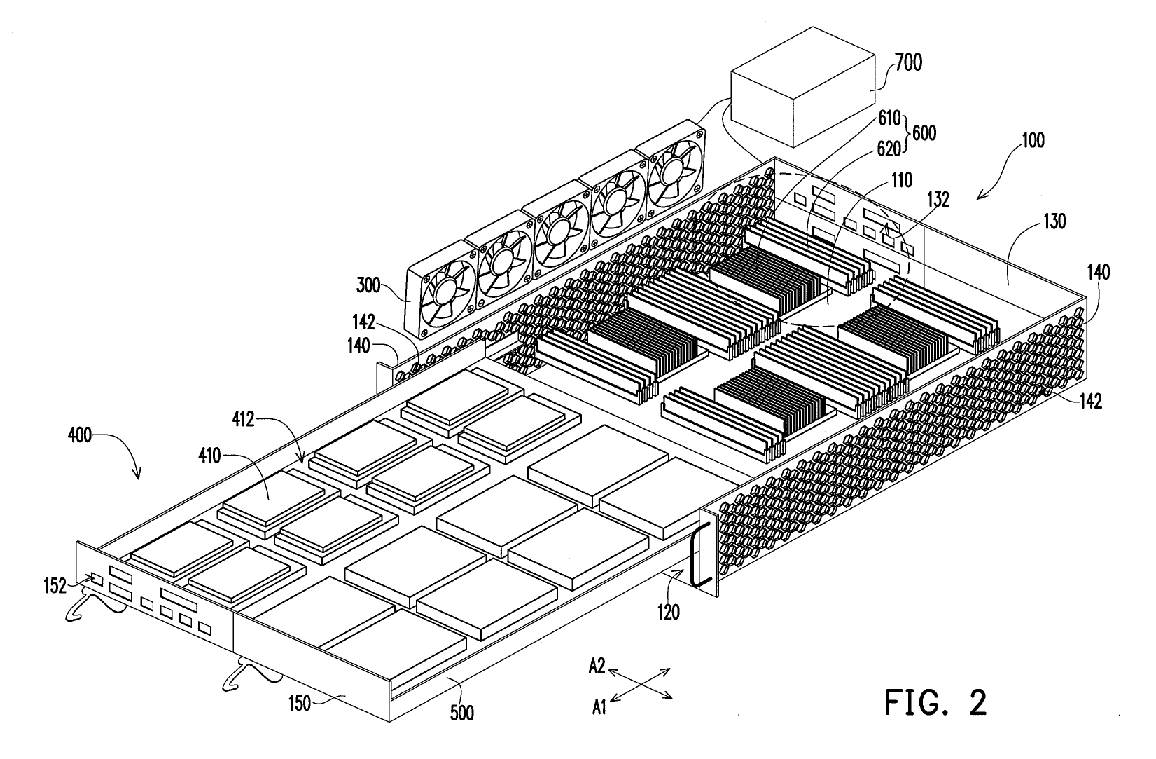

FIG. 1 illustrates a schematic diagram of a rack server according to an embodiment of the invention. FIG. 2 is a schematic diagram illustrating a case in the rack server shown in FIG. 1. In FIG. 2, a cabinet is omitted to identify a component disposition inside the case clearly. Referring to FIGS. 1 and 2, in the present embodiment, a rack server 10 includes a plurality of cases 100, a cabinet 200, a plurality of fans 300, and a plurality of replaceable modules 400. The cases 100 are disposed movably in the cabinet 200 through a plurality of tracks 210. The replaceable module 400 is disposed movably in the case 100 and can be moved into or out of the case 100 suitably along a first axis A1. Since each of the cases 100 are disposed in a similar manner in the cabinet 200, only one of the cases 100 is adopted for illustration in the following.

Referring to FIG. 2, the case 100 includes a bottom plate 110, a back panel 130 disposed upright at an end of the bottom plate 110 and a pair of side plates 140 parallel to each other. Herein, the back panel 130 is connected between the pair of side plates 140. In addition, the bottom plate 110 and the pair of side plates 140 form an opening 120 and the back panel 130 is located opposite to the opening 120. It should be noted that each of the side plates 140 has a plurality of vents 142 and the fans 300 are disposed between the cabinet 200 and one of the side plates 140, so that an air flow generated by the fans 300 flows into and out of the case 100 through the vents 142.

Additionally, in the present embodiment, the rack server 10 further includes a front panel 150, a carrying rack 500 and a mother board module 600. The mother board module 600 is disposed on the bottom plate 110. The carrying rack 500 is disposed movably above the mother board module 600. The replaceable module 400 includes a plurality of hard disks 410 disposed on the carrying rack 500 in an array. The front panel 150 is disposed on the carrying rack 500 and opposite to the back panel 130. Accordingly, the user pulls the carrying rack 500 out of the case 100 so as to perform maintenance or replacement of the hard disks 410 in the carrying rack 500. The operation inconvenience caused by pulling the case 100 out of the cabinet 200 entirely is thus prevented. However, the invention does not limit the type of the replaceable module 400 and the disposition of the replaceable module 400 inside the case 100. In another embodiment not shown in the invention, the replaceable module can also be a mother board module or a relevant electronic device simultaneously including a mother board module and a hard disk. Additionally, the rack server also includes a plurality of carrying racks, so that each of the electronic devices disposed in the case can be moved into or out of the case through the opening for installing each electronic device conveniently.

Accordingly, in the case 100 of the invention, the vents 142 is disposed on the side plate 140, and the fans 300 are disposed between the side plate 140 and the cabinet 200. Thus, the air flow generated by the fans 300 flows into and out of the case 100 along a second axis A2 though the vents 142. Here, the length of the side plates 140 in the case 100 is longer than the length of the front panel 150 and the back panel 130. Consequently, for the air flow flowing along the second axis A2 in the present embodiment, the flowing path of the air flow through the case 100 is shorter than the path of the air flow along the first axis A1 in the conventional technology. The cooling efficiency of the rack server 10 in the invention is thus increased.

Moreover, the number of the fans 300 is not limited in the invention. In another embodiment not shown in the invention, the fans 300 can also be disposed between the cabinet 200 and the side plates 140 on the two sides of the case 100 simultaneously so as to increase the air flow volume for enhancing heat dissipation.

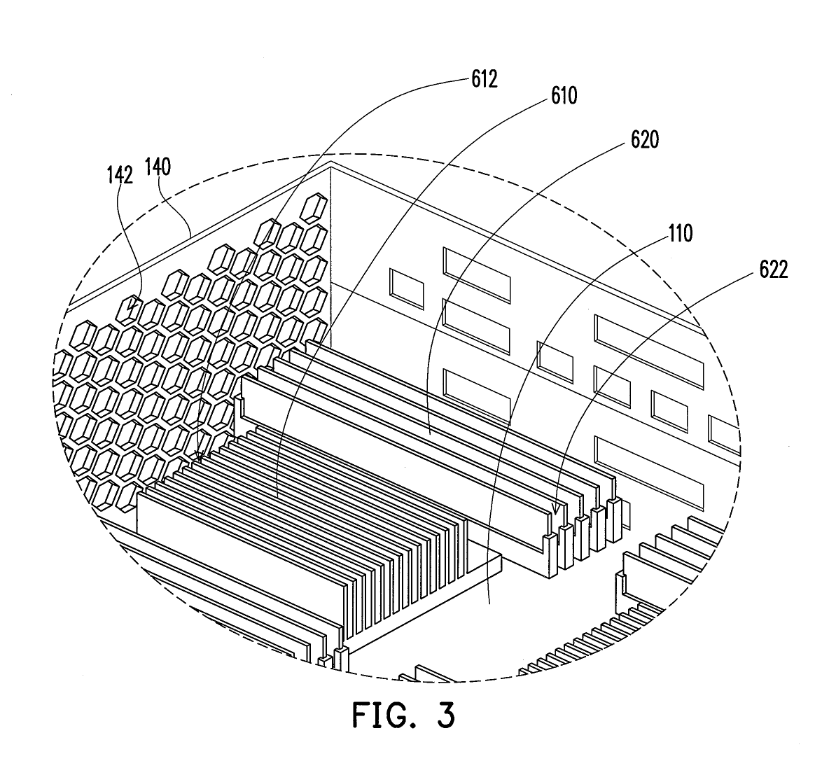

FIG. 3 illustrates a partial enlarged diagram of the case shown in FIG. 2. Referring to FIGS. 2 and 3 simultaneously, in the present embodiment, a mother board module 600 includes a plurality of heat sink fin sets 610 and a plurality of memory modules 620. Here, the memory modules 620 are disposed inside the case 100 in an array to form a plurality of first channels 622, and a plurality of second channels 612 is also formed between the fins of the heat sink fin sets 610. It should be noted that the first channel 622 and the second channel 612 are both parallel to the second axis A2. In other words, the dispositions of the memory modules 620 and the fins in the heat sink fin sets 610 are all perpendicular to the side plates 140. Furthermore, the hard disks 410 in the replaceable module 400 on the carrying rack 500 also have a similar disposition. In details, a third channel 412 is present between any two hard disks 410, where the third channel 412 is also parallel to the second axis A2. Hence, the air flow flowing from the vents 142 on one of the side plates 140 into the case 100 can flow to the vents 142 on the opposite side plate 140 undisturbed through the first channels 622, the second channels 612, and the third channel 412. Accordingly, the air flow flowing in the case 100 is not interfered by the component disposition inside the case 100, where the interference usually causes disrupted flowing of the air flow in the conventional technology so as to result in poor heat dissipation.

On the other hand, the type of channel between the electronic devices inside the case 100 is not limited in the invention. Channels formed between the electronic devices in the case 100, parallel to the second axis A2, and capable of facilitating the flowing of the air flow can all be adopted in the invention.

Comparing to the internal disposition of the case in the conventional rack server, since an air flow direction generated by the aforesaid disposition (the second axis A2) is perpendicular to a moving direction of the replaceable module 400 (the first axis A1), the fans 300 in the invention do not need to be disposed on the front panel 150 or the back panel 130 in the case 100. As a consequence, the front panel 150 and the back panel 130 of the case 100 can have a plurality of I/O openings 132 and 152 respectively for the communication of the electronic devices in the case 100 and external apparatuses, so as to enhance the functionality of the rack server 10.

Similarly, the rack server 10 further includes a power supply module 700 disposed outside of the case 100. The power supply module 700 supplies power to the fans 300 and the electronic modules in the case 100 simultaneously. For example, the power supply module 700 provides a 12 Volts direct current power to the fans 300 and the electronic modules in the case 100 directly. In the present embodiment, the electronic modules include the replaceable module 400 and the mother board module 600 disposed on the bottom plate 110. Since cables required for the power supply module 700 to supply power are also disposed outside of the case 100, the components in the case 100 are also disposed in a straightforward manner. Thus, the poor heat dissipation of the case caused by the interrupted flowing of the air flow resulted from the disposition of a large number of components and relevant cables is prevented.

In summary, in the embodiments of the invention, the air flow of the fans can flow from one side plate in the case to another side plate fluently by disposing the fans between the side plates of the case and the cabinet, disposing a plurality of vents on the side plates of the case simultaneously, and arranging the electronic devices inside the case to be in the same direction. Accordingly, the flowing path of the air flow is shortened to increase the heat dissipation efficiency in the case. Moreover, the internal disposition of the case is more straightforward so as to reduce the interference to the flowing of the air flow inside the case.

Also, the front and back panels of the case have more I/O openings as the fans and the cable thereof have been moved out of the case, such that the external communication function of the rack server can be increased indirectly.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A rack server, comprising:
a cabinet;
at least one case, disposed movably in the cabinet and having an opening and a plurality of vents;
at least one replaceable module, moved into or out of the case through the opening along a first axis; and
at least one fan, disposed between the cabinet and the case, wherein an air flow generated by the fan flows into or out of the case through the vents, and the air flow flows inside the case along a second axis, wherein the first axis is substantially perpendicular to the second axis.

2. The rack server as claimed in claim 1, wherein the case comprises:
a bottom plate;
a back panel, disposed upright on the bottom plate and opposite to the opening; and
a pair of side plates, disposed upright on the bottom plate in a parallel manner, wherein the back panel is connected between the pair of side plates and each of the side plates has the vents.

3. The rack server as claimed in claim 2, wherein the fan is located between at least one of the pair of side plates and the cabinet substantially.

4. The rack server as claimed in claim 2, further comprising at least one carrying rack disposed in the case, the carrying rack moved into or out of the case through the opening and the replaceable module disposed on the carrying rack.

5. The rack server as claimed in claim 4, wherein the case further comprises at least one front panel disposed on the carrying rack and opposite to the back panel, wherein the front panel and the back panel have a plurality of input/output openings respectively.

6. The rack server as claimed in claim 5, wherein the pair of side plates is perpendicular to the second axis substantially, and the front panel and the back panel are perpendicular to the first axis substantially.

7. The rack server as claimed in claim 1, wherein the replaceable module is a mother board module, a hard disk module, or a combination of at least one mother board module and at least one hard disk module.

8. The rack server as claimed in claim 7, wherein the mother board module comprises: at least one heat sink fin set disposed in the case, with fins of the heat sink fin set being parallel to the second axis; and
at least one memory module disposed in the case, with the memory module being parallel to the second axis.

9. The rack server as claimed in claim 7, wherein the hard disk module comprises:
a plurality of hard disks disposed in the case in an array, wherein a channel parallel to the second axis is present between any two hard disks.

10. The rack server as claimed in claim 1, further comprising:
a power supply module disposed outside of the case, supplying power to the fan and a plurality of electronic modules disposed in the case simultaneously, wherein the electronic modules comprise the replaceable module.

11. A rack server, comprising:
a cabinet;
at least one case, disposed movably in the cabinet and having an opening, the case comprising;
a bottom plate;
a back panel, disposed upright on the bottom plate and opposite to the opening;
a pair of side plates, disposed upright on the bottom plate in a parallel manner, wherein the back panel is connected between the pair of side plates and each of the side plates has a plurality of vents;
at least one replaceable module, moved into or out of the case through the opening; and
at least one fan, disposed between the cabinet and at least one of the pair of side plates, wherein an air flow generated by the fan flows into or out of the case through the vents.

12. The rack server as claimed in claim 11, further comprising:
at least one carrying rack, disposed in the case movably to be moved into or out of the case through the opening, wherein the replaceable module is disposed on the carrying rack; and
at least one front panel, disposed on the carrying rack and opposite to the back panel, wherein the front panel and the back panel have a plurality of input/output openings respectively.

13. The rack server as claimed in claim 11, wherein the replaceable module is a mother board module, a hard disk module, or a combination of at least one mother board module and at least one hard disk module.

14. The rack server as claimed in claim 13, wherein the mother board module comprises:
at least one heat sink fin set disposed in the case, with fins of the heat sink fin set being perpendicular to the pair of side plates; and
a plurality of memory modules, disposed in the case in an array, wherein a first channel is present between any two memory modules and the first channel is substantially perpendicular to the pair of side plates.

15. The rack server as claimed in claim 13, wherein the hard disk module comprises:
a plurality of hard disks, disposed in the case in an array, wherein a second channel is present between any two hard disks and the second channel is substantially perpendicular to the pair of side plates.

16. The rack server as claimed in claim 11, further comprising:
a power supply disposed outside of the case, supplying power to the fan and a plurality of electronic modules disposed in the case simultaneously, wherein the electronic modules comprise the replaceable module.

17. A rack server, comprising:
a cabinet;
at least one case, disposed movably in the cabinet and having an opening, the case comprising:
a bottom plate;
a back panel, disposed upright on the bottom plate and opposite to the opening;
a pair of side plates, disposed upright on the bottom plate in a parallel manner, wherein the back panel is connected between the pair of side plates and each of the side plates has a plurality of vents;
at least one fan, disposed between the cabinet and at least one of the pair of side plates, wherein an air flow generated by the fan flows into or out of the case through the vents;
at least one heat sink fin set disposed in the case, with fins of the heat sink fin set being perpendicular to the pair of side plates;
a plurality of memory modules, disposed in the case in an array, wherein a first channel is present between any two memory modules and the first channel is substantially perpendicular to the pair of side plates, and
a plurality of hard disks, disposed in the case in an array, wherein a second channel is present between any two hard disks and the second channel is substantially perpendicular to the pair of side plates.

18. The rack server as claimed in claim 17, further comprising:
a carrying rack, disposed in the case movably to be moved into or out of the case through the opening, wherein the hard disks, the memory modules, the heat sink fin set, or a combination of at least one hard disks and at least one memory modules and the heat sink fin set are disposed on the carrying rack; and
a front panel, disposed on the carrying rack and opposite to the back panel, wherein the front panel and the back panel have a plurality of input/output openings respectively.

19. The rack server as claimed in claim 17, further comprising:
a power supply disposed outside of the case, supplying power to the hard disks, the memory modules, the fan, and the heat sink fin.
